(19) United States
(12) Patent Application Publication
(10) Pub. No.: US 2025/0149857 A1
(43) Pub. Date: May 8, 2025

(54) OPTICAL SEMICONDUCTOR DEVICE

(71) Applicant: Lumentum Operations LLC, San Jose, CA (US)

(72) Inventor: Masaru ONGA, Sagamihara (JP)

(21) Appl. No.: 18/647,983

(22) Filed: Apr. 26, 2024

(30) Foreign Application Priority Data
Nov. 2, 2023 (JP) 2023-188508
Feb. 13, 2024 (JP) 2024-019460

(51) Int. Cl. H01S 5/125; H01S 5/042; H01S 5/223

(52) U.S. Cl. CPC H01S 5/125; H01S 5/04252; H01S 5/223

(57) ABSTRACT

An optical semiconductor device, excellent in a high heat dissipation property and a low stress property, includes: a cladding layer in which a mesa structure portion extending in a first direction is formed; an upper surface electrode including a first electrode layer and a second electrode layer thicker than the first electrode layer; a mesa structure region in which the mesa structure portion is formed; and a first adjacent region adjacent to the mesa structure portion in a second direction perpendicular to the first direction in plan view. The first electrode layer is arranged continuously from the mesa structure region to the first adjacent region. The second electrode layer includes a first part arranged in the mesa structure region, and a second part arranged in the first adjacent region. The second part has a part spaced apart from the first part in the second direction.

### CROSS-REFERENCE TO RELATED APPLICATIONS

This Patent application claims priority to Japan Patent Application No. 2024-019460, filed on Feb. 13, 2024, and to Japan Patent Application No. 2023-188508 filed on Nov. 2, 2023. The disclosures of the prior Applications are considered part of and are incorporated by reference into this Patent Application.

### TECHNICAL FIELD

The present disclosure relates generally to an optical semiconductor device.

### BACKGROUND

As one type of an optical semiconductor device, an optical semiconductor device can have a mesa structure (ridge structure) for confining light and current. For example, the optical semiconductor device can have an electrode formed so as to cover an upper surface and a side surface of the mesa structure. The electrode is in contact with a semiconductor layer in an upper portion of a ridge portion (mesa structure portion). The electrode has not only a function of driving the optical semiconductor device, but also a function of releasing heat generated in the vicinity of an optical waveguide region in the semiconductor layer to the outside, which leads to an improvement in characteristics.

### SUMMARY

The electrode in the optical semiconductor device described above can have a three-layer structure of titanium, platinum, and gold from the semiconductor layer side. Further, gold is thicker than the other two layers. All of the three layers of the electrode are arranged from the upper surface of the ridge portion across the side surface and a rising portion of the ridge portion to reach a flat end portion expanded in a direction separated away from the ridge portion, except for the vicinity of a facet of the ridge portion. The electrode being a metal and the optical waveguide region formed of a semiconductor crystal have different thermal expansion coefficients. In particular, gold has a large thermal expansion coefficient, and applies a stress to the optical waveguide because of its thickness. Thus, in some cases, characteristics as designed of the optical semiconductor device cannot be achieved. In some cases, gold is arranged only in an upper portion of the mesa structure portion. With this structure, it is considered that the stress applied to the semiconductor layer is reduced (comparatively). Meanwhile, gold has an excellent heat dissipation property, and hence the heat dissipation property is degraded in this structure (comparatively). Thus, in some cases, the designed characteristics cannot be achieved.

Some implementations described herein provide an optical semiconductor device provides a high heat dissipation property and in a low stress property.

Some implementation described herein comprise an optical semiconductor device that includes: a substrate; an optical function layer arranged on the substrate; a cladding layer arranged on the optical function layer, the cladding layer having at least a part in which a mesa structure portion extending in a first direction is formed; an upper surface electrode including a first electrode layer and a second electrode layer which is thicker than the first electrode layer and is arranged on the first electrode layer, the upper surface electrode being arranged on at least a part of the cladding layer; a mesa structure region in which the mesa structure portion is formed; and a first adjacent region adjacent to the mesa structure portion in a second direction perpendicular to the first direction in plan view. The first electrode layer is arranged continuously from the mesa structure region to the first adjacent region. The second electrode layer includes a first part arranged in the mesa structure region, and a second part arranged in the first adjacent region. The second part has a part spaced apart from the first part in the second direction.

### BRIEF DESCRIPTION OF THE DRAWINGS

FIG. 1 is an example of a top view of an optical semiconductor device according to a first example implementation of the present invention.

FIG. 2A is a schematic sectional view taken along the line IIA-IIA of the optical semiconductor device illustrated in FIG. 1.

FIG. 2B is a schematic sectional view taken along the line IIB-IIB of the optical semiconductor device illustrated in FIG. 1.

FIG. 3 is a schematic sectional view taken along the line IIA-IIA to illustrate Modification Example 1 of the first example implementation.

FIG. 4 is an example of a top view of an optical semiconductor device according to Modification Example 2 of the first example implementation.

FIG. 5 is a schematic sectional view taken along the line V-V to illustrate Modification Example 2 of the first example implementation.

FIG. 6 is an example of a top view of an optical semiconductor device according to Modification Example 3 of the first example implementation.

FIG. 7 is a schematic sectional view taken along the line VII-VII to illustrate Modification Example 3 of the first example implementation.

FIG. 8 is a schematic sectional view taken along the line IIA-IIA to illustrate Modification Example 4 of the first example implementation.

FIG. 9 is a schematic sectional view taken along the line IIA-IIA to illustrate Modification Example 5 of the first example implementation.

FIG. 10 is a schematic sectional view taken along the line IIA-IIA to illustrate Modification Example 6 of the first example implementation.

FIG. 11 is an example of a top view of an optical semiconductor device according to a second example implementation of the present invention.

FIG. 12 is a schematic sectional view taken along the line XII-XII of the optical semiconductor device illustrated in FIG. 11.

### DETAILED DESCRIPTION

Some implementations are specifically described in detail in the following with reference to drawings. In the drawings, the same members are denoted by the same reference numerals and have the same or equivalent functions, and a repetitive description thereof may be omitted for the sake of simplicity. Note that, the drawings referred to in the following are only for illustrating the example implementations, and are not necessarily drawn to scale.

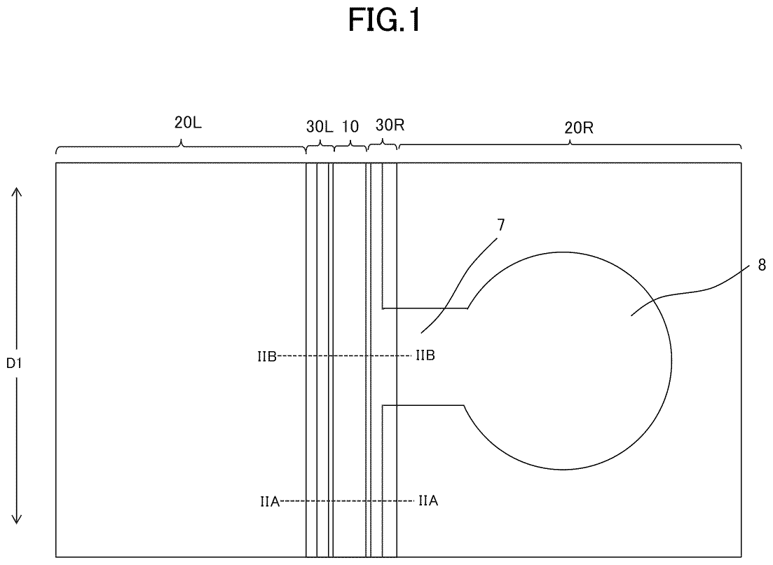

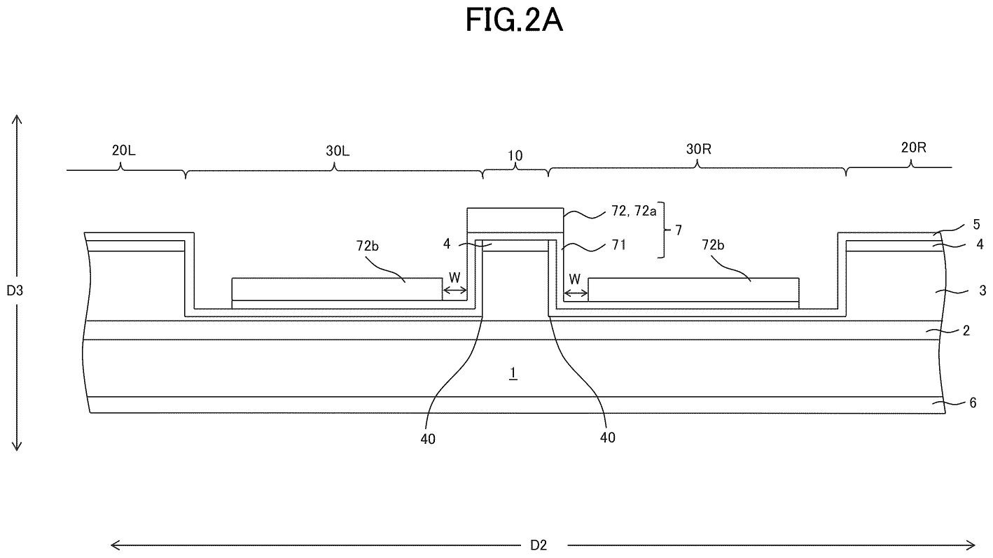

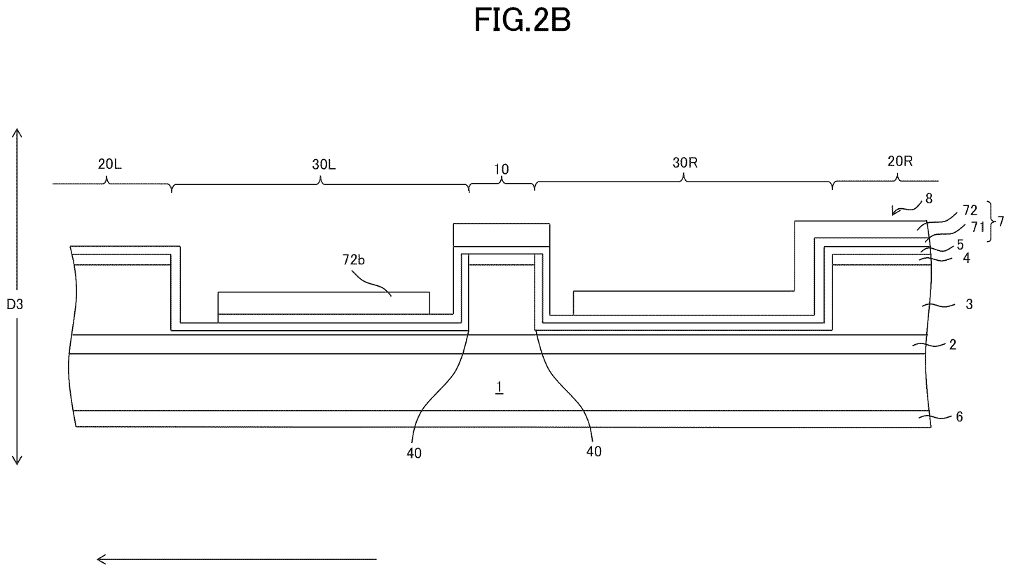

FIG. 1 is a top view of an optical semiconductor device according to a first example implementation of the present invention. FIG. 2A is a schematic sectional view taken along the line IIA-IIA of FIG. 1. FIG. 2B is a schematic sectional view taken along the line IIB-IIB of FIG. 1. The optical semiconductor device may have a function of guiding, emitting, absorbing, amplifying, or modifying light. The optical semiconductor device may be a semiconductor laser, and this semiconductor laser may be a distributed feedback (DFB) semiconductor laser. The optical semiconductor device may be a modulator integrated optical semiconductor device (for example, a modulator integrated laser) in which a modulating unit is monolithically integrated with a semiconductor laser. With the modulator integrated laser, continuous light emitted by injecting a drive current to a laser unit is modulated by the modulating unit so that signal light is output. This modulating unit may be an electro-absorption modulator. In the modulator integrated laser, an electrode structure for implementing the first example implementation may be present in the laser unit or the modulator unit.

The optical semiconductor device may include a substrate 1. The substrate 1 may be a semiconductor substrate of a conductivity type (for example, “n” type). An optical function layer 2 may be formed on one surface of the substrate 1. When the optical semiconductor device is a semiconductor laser, the optical function layer 2 functions as an active layer. When the optical semiconductor device is a modulator, the optical function layer 2 functions as an absorption layer. The optical function layer 2 may have a multiple quantum well (MQW) structure, or may be a bulk semiconductor layer. A cladding layer may be included between the substrate 1 and the optical function layer 2. When no cladding layer is included, the substrate 1 functions as a lower cladding layer. A cladding layer 3 may be formed on an upper surface of the optical function layer 2. The cladding layer 3 may be arranged on the optical function layer 2, and may have at least a part in which a mesa structure portion extending in a predetermined direction (hereinafter referred to as “first direction D1”) is formed. The cladding layer 3 may be a layer having an effective refractive index less than that of the optical function layer 2. The cladding layer 3 may be a semiconductor layer of a conductivity type (for example, “p” type). A contact layer 4 may be formed on an upper surface of the cladding layer 3. The contact layer 4 may be electrically and physically in contact with an upper surface electrode 7 on an upper surface of a mesa structure portion to be described later. The optical function layer 2, the cladding layer 3, and the contact layer 4 may be semiconductor layers. Other semiconductor layers, such as an optical confinement layer, may be included above or below the optical function layer 2. Further, when the optical semiconductor device is a semiconductor laser, a grating layer may be included in a layer above or below the optical function layer 2. The semiconductor layer may be, for example, an InP-based layer. Specifically, the substrate 1 and the cladding layer 3 may be InP layers, the optical function layer 2 may be InGaAsP or InGaAlAs, and the contact layer 4 may be InGaAs. However, those materials are merely examples, and other materials may be used.

The optical semiconductor device may include a mesa structure region 10 in which the mesa structure portion is formed, a bank region 20 in which a bank portion having the same layer structure as that of the mesa structure portion is formed, and an adjacent region 30 adjacent to the mesa structure portion in a direction perpendicular to the first direction D1 in plan view (hereinafter referred to as “second direction D2”). In this case, the mesa structure region 10 and the bank region 20 only represent regions formed of semiconductor layers. The bank region 20 may be present on a side of the adjacent region 30 opposite to the mesa structure region 10. The adjacent region 30 may be arranged on both sides of the mesa structure region 10 in the second direction. The bank region 20 may be arranged adjacent to the adjacent region 30 and on a side opposite to the mesa structure region 10. As illustrated in FIG. 2A and FIG. 2B, the bank region 20 and the adjacent region 30 may be arranged on each of both sides of the mesa structure region 10. In the following, when the bank region 20 and the adjacent region 30 arranged on the right side and the bank region 20 and the adjacent region 30 arranged on the left side may be distinguished from each other, the bank region 20 and the adjacent region 30 arranged on the right side may be referred to as “first bank region 20R” and “first adjacent region 30R,” respectively. Similarly, the bank region 20 and the adjacent region 30 arranged on the left side may be referred to as “second bank region 20L” and “second adjacent region 30L,” respectively. The mesa structure portion and the bank portion at least include the cladding layer 3 and the contact layer 4. A position of a lower surface of an insulating film 5 (described later) provided in the adjacent region 30 may be located inside of the cladding layer 3 in the bank region 20, but the position is not limited thereto, and may be located in other layers. As described later, an electric signal may be input (currents may be injected) to the semiconductor layer via the contact layer 4 in an upper portion of the mesa structure portion. The electric signal may be transmitted to the optical function layer 2 in a lower portion of the mesa structure portion. At this time, light may be distributed mainly in the optical function layer 2 in a growth direction of the semiconductor layers (hereinafter referred to as “third direction D3”). In addition, light may be distributed mainly in the mesa structure portion in the second direction D2 perpendicular to the third direction D3. A region in which light may be distributed is, in other words, an optical waveguide region.

The insulating film 5 may be formed from a side surface of the mesa structure portion across the adjacent region 30 to an upper surface of the bank region 20. The insulating film 5 is, for example, silicon oxide, and functions as a protection film for the semiconductor layer. The insulating film 5 may be arranged so as to avoid the upper surface of the mesa structure portion.

The upper surface electrode 7 may be provided on the upper surface of the mesa structure portion. On a surface of the substrate 1 opposite to a surface on which the upper surface electrode 7 is arranged, a lower surface electrode 6 may be formed. In this case, the lower surface electrode 6 and the upper surface electrode 7 may be metal films. The expressions of “upper surface” and “lower surface” do not have physical meanings, and only indicate two electrodes connected to respective semiconductor layers having conductivity types different from each other, which may be arranged so as to sandwich the optical function layer 2. In this case, an electrode on a side electrically connected to the cladding layer 3 may be referred to as “upper surface electrode 7,” and an electrode on a side electrically connected to the substrate 1 may be referred to as “lower surface electrode 6.” For example, the lower surface electrode 6 may have a structure connected to the substrate 1 on the surface on which the mesa structure portion is formed.

The upper surface electrode 7 may include a first electrode layer 71 and a second electrode layer 72 which may be thicker than the first electrode layer 71 and may be arranged on the first electrode layer 71. The upper surface electrode 7 may be arranged on at least a part of the cladding layer 3. Specifically, the upper surface electrode 7 may include the first electrode layer 71 arranged on a side closer to the semiconductor layer and the second electrode layer 72 arranged on the first electrode layer 71. The first electrode layer 71 may be arranged continuously from the mesa structure region 10 to the first adjacent region 30R. The first electrode layer 71 has, for example, in the first example implementation, a two-layer structure in which Ti and Pt may be grown in the stated order from the semiconductor layer side. Ti may be arranged for the purpose of improving adhesion between the semiconductor layer (in this case, the contact layer 4) and the electrode layer arranged on the upper side of the semiconductor layer, and forming an ohmic electrode. Pt may be arranged in order to prevent a metal included in the electrode layer arranged on the upper side of the semiconductor layer from being dispersed to the semiconductor layer. The first electrode layer 71 may have, other than a multilayer structure of two layers, a multilayer structure of three layers or more, or may include a metal other than Ti or Pt. The second electrode layer 72 may be formed of a metal layer containing at least Au, or an alloy thereof. The second electrode layer 72 may be a layer thicker than the first electrode layer 71 in order to improve a heat dissipation property. A difference in thermal expansion coefficient or a difference in Young's modulus between the second electrode layer 72 and the semiconductor layer or the insulating film 5 may become a cause of a stress to be applied to the semiconductor layer. As an example of a thickness of each layer, the first electrode layer 71 may include a Ti layer of 100 nm and a Pt layer of 100 nm, and may have a thickness of 200 nm in total. The second electrode layer 72 may be an Au layer having a thickness of 500 nm. The thicknesses of the three electrode layers are merely examples, and may be other thicknesses. It may be preferred that the thickness of the first electrode layer 71 be, for example, 50 nm or more and 250 nm or less in total. Further, it may be preferred that the second electrode layer 72 be 200 nm or more and 1,000 nm or less. However, the thicknesses may be not limited thereto.

The upper surface electrode 7 may include a pad portion 8 arranged in an upper portion of the bank portion in the first bank region 20R for electrical connection to the outside. The pad portion 8 may have a shape obtained by combining a substantially circular shape and a rectangular shape, but the shape is not limited thereto. As illustrated in FIG. 2B, the pad portion 8 may include the first electrode layer 71 and the second electrode layer 72. The second electrode layer 72 of the pad portion 8 may be spaced apart in the second direction D2 from the second electrode layer 72 (first part 72a to be described later) on the upper surface of the mesa structure portion. The rectangular region of the pad portion 8 may be connected to a part of the upper surface electrode 7 arranged in the first adjacent region 30R. The electrode 7 may be arranged to extend in the first direction D1 in which the mesa structure portion extends, except for the pad portion 8. In this case, the electrode 7 may be arranged in a shape conforming to the mesa structure portion, from a facet (upper end of FIG. 1) of the optical semiconductor device to another facet (lower end of FIG. 1) thereof. The electrode 7 may be arranged up to a portion slightly on an inner side of the facet (inner side as viewed in the first direction D1 of FIG. 1), and may be prevented from being arranged up to the facet. The upper surface electrode 7 may be arranged so as to expand to the upper surface of the bank portion.

As illustrated in FIG. 2A, the first electrode layer 71 may be arranged from the upper surface of the mesa structure portion across the side surface of the mesa structure portion to a part of the adjacent region 30. As illustrated in FIG. 2A, in at least a part of the side surface of the mesa structure portion, the insulating film 5 may be arranged between the first electrode layer 71 and the semiconductor layer (in this case, the cladding layer 3 and the contact layer 4). Meanwhile, the second electrode layer 72 may be arranged only on the upper surface of the mesa structure region 10 and a part of the adjacent region 30. In other words, the second electrode layer 72 may include a first part 72a arranged in the mesa structure region 10 (upper surface of the mesa structure portion), and a second part 72b arranged in the adjacent region 30. The second part 72b may be arranged in both of the first adjacent region 30R and the second adjacent region 30L. That is, the second part 72b may have a part spaced apart from the first part 72a in the second direction D2. One feature of the first example implementation resides in that the second electrode layer 72 may be arranged so as to avoid the vicinity of a boundary between the adjacent region 30 and the mesa structure region 10 (side surface of the cladding layer 3 included in the mesa structure portion, hereinafter referred to as “rising portion 40”), and the first electrode layer 71 may be arranged continuously from the upper surface of the mesa structure region 10 across the side surface of the mesa structure portion to the adjacent region 30. In other words, the second electrode layer 72 may be arranged so as to have spacing between the mesa structure region 10 and the adjacent region 30. In this case, the first part 72a and the second part 72b may have the same layer structure and the same thickness. The same thickness means that the layers may be formed in the same process at the same time, and the layers may have different thicknesses in a range of manufacturing fluctuations. However, the first part 72a and the second part 72b are not limited thereto, and the first part 72a and the second part 72b may have different layer structures or may have the same structure but different thicknesses.

The rising portion 40 represents a region between a vertical surface (surface along the third direction D3) of the mesa structure portion and an end portion on the mesa structure portion side of the insulating film 5 arranged in the adjacent region 30 along the second direction D2. The rising portion 40 may not be limited to a right angle shape. For example, the rising portion 40 may include a curved line or may be an inclined surface. The rising portion 40 may be a part in which the upper surface electrode 7 and the optical waveguide region come closest to each other, and may be also a portion at which the shape of the semiconductor layer changes. Accordingly, a stress applied to the rising portion 40 greatly affects the semiconductor layer, particularly the optical waveguide region. In the first example implementation, the thick second electrode layer 72 that causes generation of a strong stress may be prevented from being arranged in the vicinity of the rising portion 40 so that the stress caused by the upper surface electrode 7 may be reduced. The reduction of the stress to the optical function layer 2 in the optical waveguide region contributes to improvement of the characteristics of the optical semiconductor device. The first part 72a may be required to be arranged so as to form an electrical and thermal contact with the semiconductor layer in the upper portion of the mesa structure portion together with the first electrode layer 71. The second part 72b provides an effect of dissipating and uniformizing heat transferred from the optical function layer 2 in a waveguide direction, and contributes to improvement of the characteristics of the optical semiconductor device. When the second part 72b is excessively separated away from the rising portion 40, the heat dissipation property may be degraded. In this case, a distance between a side surface of the second part 72b on the mesa structure portion side and a side surface on a side opposite to the mesa structure portion side (side surface facing the second part 72b) of the first electrode layer 71 arranged on the side surface of the mesa structure portion may be represented by W. From a viewpoint of achieving both of the stress reduction and the heat dissipation property, it may be preferred that W be larger than 0 and equal to or less than the thickness of the second part 72b. In this case, the thickness of the second part 72b refers to a thickness in the third direction D3.

The first electrode layer 71 may be also arranged in the vicinity of the rising portion 40. From the viewpoint of stress reduction, it may be preferred that the first electrode layer 71 also have spacing similar to the second electrode layer 72. However, the rising portion 40 may be a region having large heat generation, and the first electrode layer 71 may be also arranged in the vicinity of the rising portion 40 in order to ensure the heat dissipation property. In this case, the phrase “arranged in the vicinity of the rising portion 40” represents that the first electrode layer 71 may be integrally arranged continuously from the side surface of the mesa structure portion to the upper surface of the insulating film 5 in the adjacent region 30. However, influence of a stress is unignorable when the first electrode layer 71 is too thick, and hence it may be preferred that the thickness of the first electrode layer 71 be equal to or less than the half of the thickness of the second electrode layer 72.

In the first example implementation, the second electrode layer 72 may have spacing on each of both sides of the mesa structure region 10, but the second electrode layer 72 may have a structure having spacing on only one side. Further, the spacing region (region of the adjacent region 30 in which no second electrode layer 72 is arranged in the second direction D2) may be present only in a part of the optical semiconductor device in a direction in which the mesa structure portion extends (first direction D1). The phrase “having spacing on only one side” also may include a case in which the second part 72b (excluding the pad portion 8) is not arranged in the adjacent region 30 on one side, and the first part 72a and the second part 72b may be continuous in the adjacent region 30 on another side. The phrase “the first part 72a and the second part 72b may be continuous” represents a case in which W is 0. Further, W is not always required to be the same on the right and left sides of the mesa structure portion. For example, in FIG. 2A, W on the left side may be smaller or larger than W on the right side. However, in consideration of right/left balance of the stress applied to the mesa structure portion, it may be preferred that W on the right side and W on the left side be equal to each other.

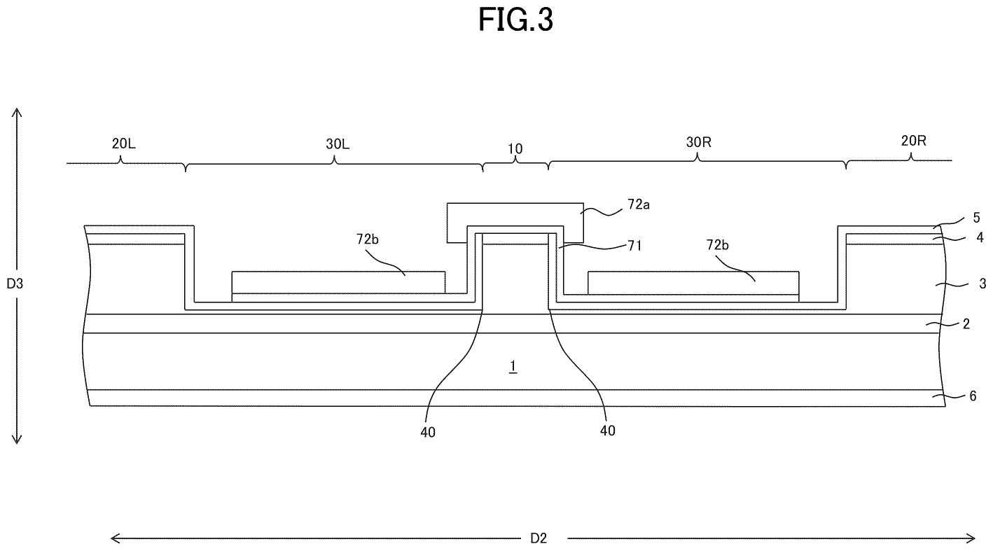

FIG. 3 is a schematic sectional view taken along the line IIA-IIA to illustrate Modification Example 1 of the optical semiconductor device of the first example implementation. The difference from the first example implementation resides in the shape of the first part 72a arranged in the upper portion of the mesa structure portion. The first part 72a may be arranged from the upper surface of the mesa structure portion to a part of the side surface of the mesa structure portion. However, the first part 72a and the second part 72b arranged in the adjacent region 30 may be spaced apart from each other. This structure can promote heat dissipation from the side surface of the mesa structure portion while maintaining the stress reduction effect.

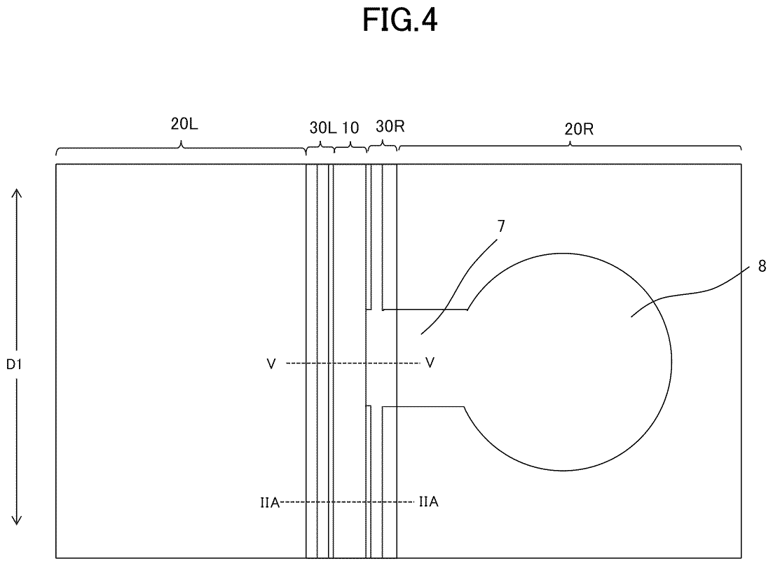

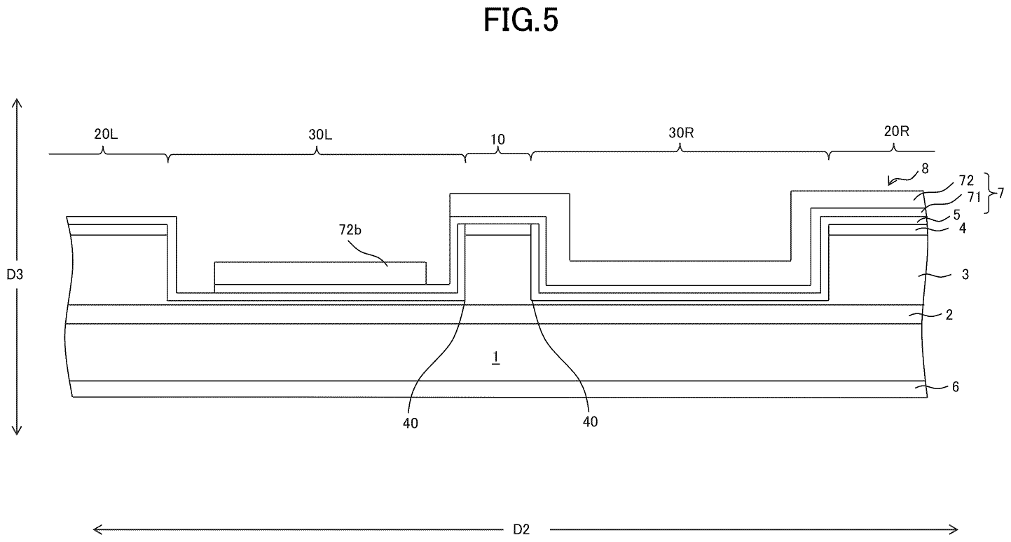

FIG. 4 is a top view of an optical semiconductor device according to Modification Example 2 of the optical semiconductor device of the first example implementation. FIG. 5 is a schematic sectional view taken along the line V-V of FIG. 4. The optical semiconductor device of Modification Example 2 may be different from the first example implementation only in the shape of the second electrode layer 72. In Modification Example 2, the second electrode layer 72 may have a part continuous in the second direction D2 from the upper surface of the mesa structure portion to the pad portion 8. In other words, a part of the second part 72b may be continuous with the first part 72a. In other regions, similar to the first example implementation, the first part 72a and the second part 72b may be spaced apart from each other. Modification Example 2 has a uniform electrode structure from the pad portion 8 to the upper portion of the mesa structure portion, and hence has relatively uniform electrical resistance and is excellent from the viewpoint of high-frequency characteristics.

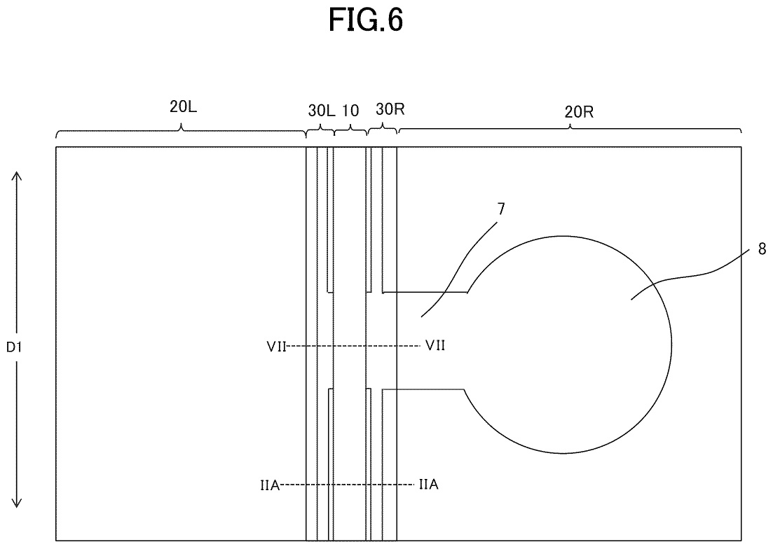

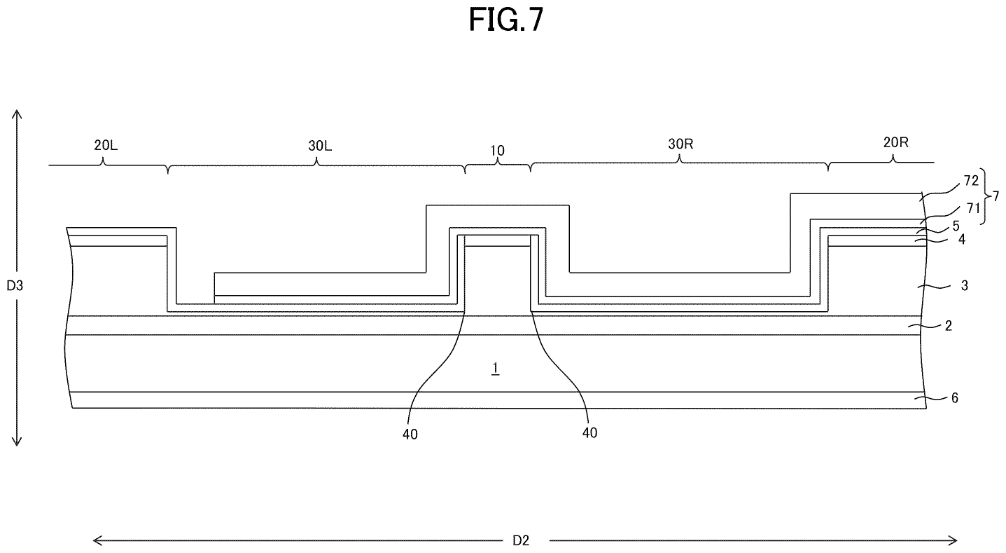

FIG. 6 is a top view of an optical semiconductor device according to Modification Example 3 of the optical semiconductor device of the first example implementation. FIG. 7 is a schematic sectional view taken along the line VII-VII of FIG. 6. The optical semiconductor device of Modification Example 3 may be different from the first example implementation only in the shape of the second electrode layer 72. The shape of the second electrode layer 72 in the first adjacent region 30R and the first bank region 20R (right side) may be the same as that of Modification Example 2 of the first example implementation. In Modification Example 3, the shape of the second electrode layer 72 in the second adjacent region 30L and the second bank region 20L (left side) may be different from that of Modification Example 2. The second electrode layer 72 may have a part continuous in the second direction D2 from the first adjacent region 30R across the upper surface of the mesa structure portion to the second adjacent region 30L. That is, the first part 72a and the second part 72b may be continuous in the second direction D2 also in a part of the second adjacent region 30L. In the first direction D1 in which the mesa structure portion extends, a length with which the first part 72a and the second part 72b may be continuous is substantially the same between the right and left sides. In a case of a structure in which the first part 72a and the second part 72b are continuous in the second direction D2 as described above, the stress to the optical waveguide region may be increased. In the case of the structure of Modification Example 2, the stress to the mesa structure portion may be increased only on the right side, and the stress balance may be different between the right and left sides. Meanwhile, in Modification Example 3, also on the left side, the first part 72a and the second part 72b may be continuous with a similar width (length in the first direction D1), and thus the stress balance between the right and left sides may be better as compared to Modification Example 2. The influence caused by the stress on the characteristics of the optical semiconductor device may be affected by not only the magnitude of the stress but also the balance of the stress, and hence Modification Example 3 provides an effect of reducing the influence on the characteristics. Further, the second electrode layer 72 excellent in heat dissipation property may be arranged in a part of the side surface of the mesa structure portion, and hence Modification Example 3 is also excellent from the viewpoint of heat dissipation property.

As described above, the first part 72a and the second part 72b are not always required to be completely spaced apart from each other in the entire region in plan view, and the effect of the present invention may be obtained as long as the first part 72a and the second part 72b are spaced apart from each other in the second direction D2 in a part in the direction in which the mesa structure portion extends. As the size of the spacing region becomes larger, the stress to be applied to the semiconductor layer by the second electrode layer 72 becomes smaller. Conversely, as the size of the spacing region becomes smaller, the heat dissipation property becomes better. The part in which the first part 72a and the second part 72b are spaced apart from each other in the second direction D2 may be preferably 50% or more of the length in the first direction D1, more preferably 80% or more thereof. Thus, satisfactory characteristics can be obtained.

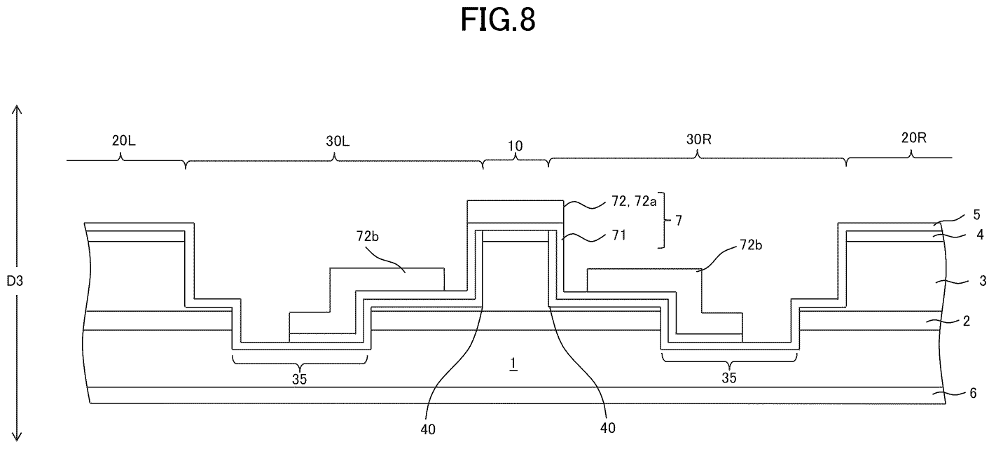

FIG. 8 is a schematic sectional view taken along the line IIA-IIA of an optical semiconductor device according to Modification Example 4 of the optical semiconductor device of the first example implementation. The difference from the first example implementation resides in that an isolation groove 35 may be formed in the adjacent region 30. A bottom surface of the isolation groove 35 may be lower than the cladding layer 3 and the optical function layer 2 and reaches the substrate 1. The isolation groove 35 may have an effect of confining, for example, currents injected into the mesa structure portion in a region (optical waveguide region) sandwiched by two isolation grooves 35, and contributes to improvement of characteristics of the optical semiconductor device. In Modification Example 4, the second part 72b covers a side surface of the isolation groove 35 on the mesa structure portion side. In other words, the second part 72b may be formed continuously from the bottom surface of the adjacent region 30 on the mesa structure portion side to the bottom surface of the isolation groove 35. In the optical semiconductor device, the optical function layer 2 generates heat most. On the side surface of the isolation groove 35 on the mesa structure portion side, the optical function layer 2 may be in contact with the insulating film 5 without any other semiconductor layer interposed therebetween. When the second part 72b excellent in heat dissipation property is disposed in this region, a high heat dissipation property may be ensured. Similarly to other modification examples, the second electrode layer 72 may be arranged so as to avoid the vicinity of the rising portion 40, and hence the above-mentioned stress reduction effect can also be obtained.

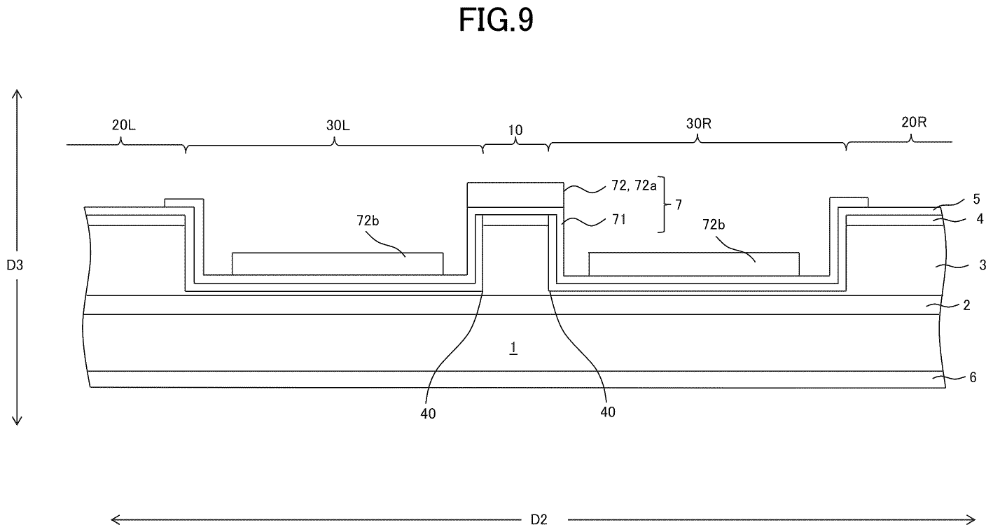

FIG. 9 is a schematic sectional view taken along the line IIA-IIA of an optical semiconductor device according to Modification Example 5 of the optical semiconductor device of the first example implementation. The difference from the first example implementation resides in that the first electrode layer 71 may be continuous from the upper surface of the mesa structure portion across the first adjacent region 30R to the upper surface of the bank portion. An end portion of the first electrode layer 71 and an end portion of the second part 72b may be not always required to match each other. The second part 72b may be arranged to reach the upper surface of the bank portion, but the stress to the semiconductor layer may be increased. Meanwhile, a region separated away from the mesa structure portion may have a small heat generation amount, and the heat dissipation may be sufficient as long as the first electrode layer 71 is arranged. Accordingly, the heat dissipation characteristic does not change so much even when the second part 72b (second electrode layer 72) is arranged up to the upper surface of the bank portion. Meanwhile, the stress may be increased, and hence there may be a fear of causing influence on the characteristics. Modification Example 5 can improve the heat dissipation property.

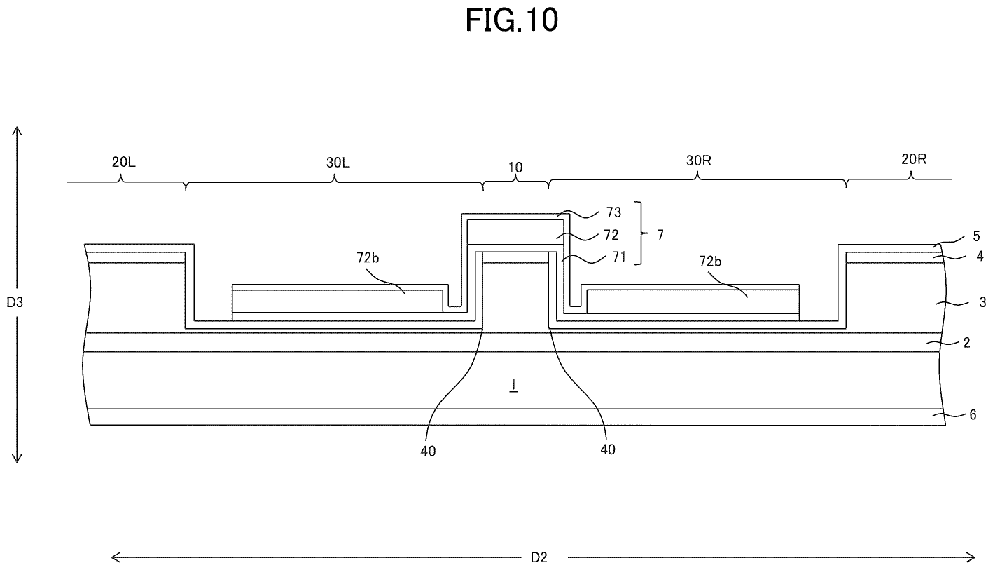

FIG. 10 is a schematic sectional view taken along the line IIA-IIA of an optical semiconductor device according to Modification Example 6 of the optical semiconductor device of the first example implementation. The difference from the first example implementation resides in that the upper surface electrode 7 further may include a third electrode layer 73 which may be arranged on the second electrode layer 72 and may be thinner than the second electrode layer 72. The third electrode layer 73 has, for example, a two-layer structure of a Pt layer and a Au layer, but the third electrode layer 73 is not limited thereto. The third electrode layer 73 may be thinner than the second electrode layer 72. It may be preferred that the thickness of the third electrode layer 73 be equal to or less than the half of the thickness of the second electrode layer 72. More preferably, it may be desired that a total thickness of the first electrode layer 71 and the third electrode layer 73 be equal to or less than the half of the thickness of the second electrode layer 72. The third electrode layer 73 may be continuous in the second direction from the upper surface of the mesa structure portion across the side surface of the mesa structure portion to the first adjacent region 30R. The present invention can obtain its effect as long as, among the plurality of metal layers (electrode layers), the thickest layer may have a spacing part between the upper surface of the mesa structure portion and the adjacent region 30.

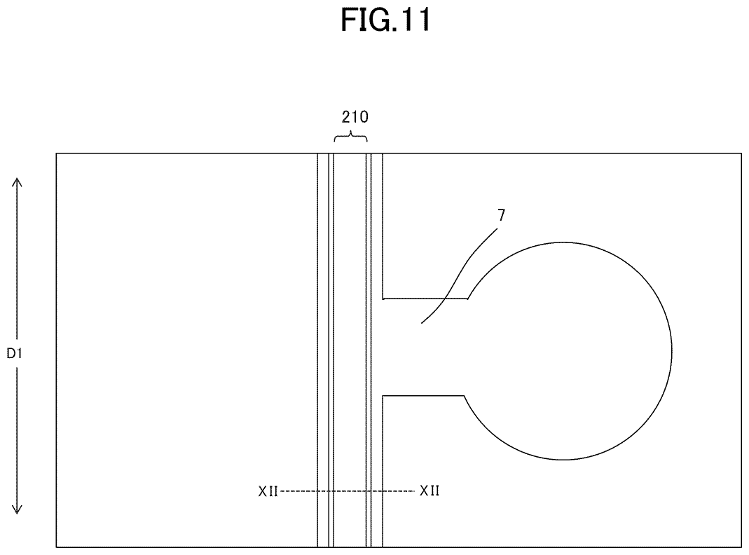

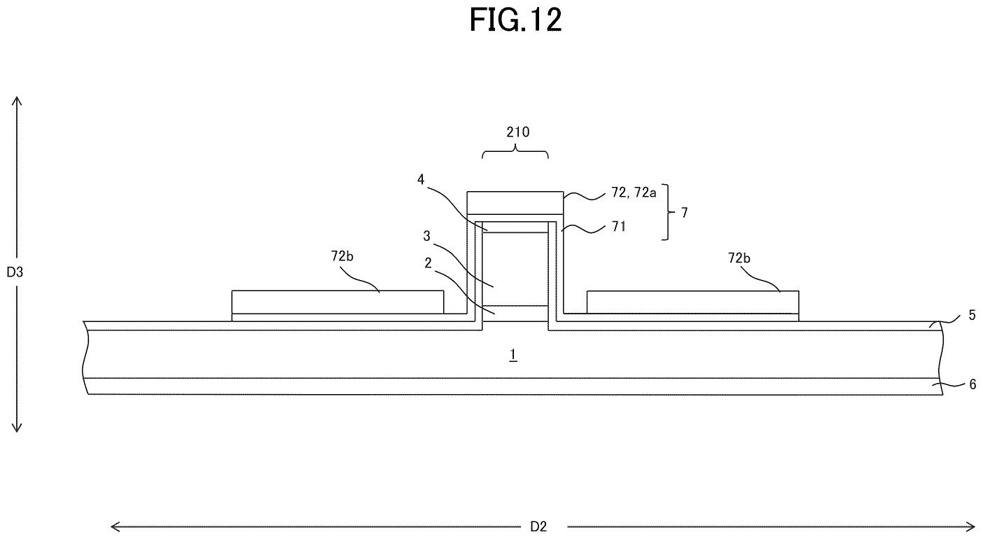

FIG. 11 is a top view of an optical semiconductor device according to a second example implementation of the present invention. FIG. 12 is a schematic sectional view taken along the line XII-XII of FIG. 11. The layer structure of the semiconductor of the optical semiconductor device according to the second example implementation may be the same as that of the optical semiconductor device according to the first example implementation. In the second example implementation, a mesa structure portion 210 at least may include the optical function layer 2, the cladding layer 3, and the contact layer 4.

In the second example implementation, a region other than the mesa structure portion 210 in which the mesa structure portion is provided may be flat, and the second part 72b may be arranged in this flat region (adjacent region). A bank portion may be arranged similarly to the first example implementation. Similarly to the first example implementation, the first part 72a arranged in the upper portion of the mesa structure portion and the second part 72b arranged in the flat region may be spaced apart from each other in the second direction D2, and the second electrode layer 72 may be arranged so as to avoid the rising portion of the mesa structure portion. Accordingly, an effect similar to that of the first example implementation may be obtained. In particular, in a case of a structure in which, as viewed from the substrate 1, the lower surface of the optical function layer 2 may be arranged at a position closer to the substrate 1 than the upper surface of the first electrode layer 71, the stress reduction effect may be large.

The present invention provides both of the high heat dissipation property and the low stress property in the optical semiconductor device including the mesa structure portion. The embodiments of the present invention include the first electrode layer arranged in contact with the mesa structure portion and the second electrode layer arranged on the first electrode layer. The first electrode layer may be arranged continuously from the upper surface of the mesa structure portion to the adjacent region. The second electrode layer may be arranged on the upper surface of the mesa structure portion and the adjacent region, but this state may be achieved by forming the first part arranged on the upper surface of the mesa structure portion and the second part arranged in the adjacent region so as to be spaced apart from each other. The first part and the second part may not be continuous in a region of 50% or more, preferably 80% or more, in the first direction D1 in which the mesa structure portion extends. The first electrode layer may be thinner than the second electrode layer. The second part of the second electrode layer arranged in the adjacent region may not be connected to the first electrode layer on the side surface of the mesa structure portion, and may be arranged at a position separated from the side surface of the first electrode layer by a distance equal to or less than the thickness of the second part. The mesa structure portion at least may include the cladding layer arranged above the optical function layer. The mesa structure portion may include the optical function layer.

While there have been described what may be at present considered to be certain implementations of the invention, it will be understood that various modifications may be made thereto, and it is intended that the appended claims cover all such modifications as fall within the true spirit and scope of the invention.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical semiconductor device, comprising:
a substrate;
an optical function layer arranged on the substrate;
a cladding layer arranged on the optical function layer, the cladding layer having at least a part in which a mesa structure portion extending in a first direction is formed;
an upper surface electrode including a first electrode layer and a second electrode layer which is thicker than the first electrode layer and is arranged on the first electrode layer, the upper surface electrode being arranged on at least a part of the cladding layer;
a mesa structure region in which the mesa structure portion is formed; and
a first adjacent region adjacent to the mesa structure portion in a second direction perpendicular to the first direction in plan view,
wherein the first electrode layer is arranged continuously from the mesa structure region to the first adjacent region,
wherein the second electrode layer includes a first part arranged in the mesa structure region, and a second part arranged in the first adjacent region, and
wherein the second part has a part spaced apart from the first part in the second direction.

2. The optical semiconductor device according to claim 1, wherein, in a part in which the first part and the second part are spaced apart from each other, a distance between a side surface of the second part on the mesa structure portion side and a side surface facing the second part of the first electrode layer arranged on a side surface of the mesa structure portion is larger than 0 and smaller than a thickness of the second part.

3. The optical semiconductor device according to claim 1, wherein the first part is arranged on a part of a side surface of the mesa structure portion.

4. The optical semiconductor device according to claim 1, further comprising, on a side of the first adjacent region opposite to the mesa structure portion, a bank region in which a bank portion is formed, the bank portion having the same layer structure as a layer structure of the mesa structure portion,
wherein the upper surface electrode includes a pad portion in the bank region, and
wherein the second electrode layer has a part continuous in the second direction from an upper surface of the mesa structure portion to the pad portion.

5. The optical semiconductor device according to claim 1, further comprising a second adjacent region adjacent to the mesa structure portion on a side opposite to the first adjacent region,
wherein the second electrode layer has a part continuous in the second direction from the first adjacent region across an upper surface of the mesa structure portion to the second adjacent region.

6. The optical semiconductor device according to claim 1, wherein a part in which the first part and the second part are spaced apart from each other in the second direction is 50% or more of a length in the first direction.

7. The optical semiconductor device according to claim 1, wherein a part in which the first part and the second part are spaced apart from each other in the second direction is 80% or more of a length in the first direction.

8. The optical semiconductor device according to claim 1,
wherein the first adjacent region further includes an isolation groove having the substrate as a bottom surface, and
wherein the second part is arranged on a side surface of the isolation groove on the mesa structure portion side.

9. The optical semiconductor device according to claim 1, further comprising, on a side of the first adjacent region opposite to the mesa structure portion, a bank region in which a bank portion is formed, the bank portion having the same layer structure as a layer structure of the mesa structure portion,
wherein the first electrode layer is continuous from an upper surface of the mesa structure portion across the first adjacent region to an upper surface of the bank portion.

10. The optical semiconductor device according to claim 9, wherein the second electrode layer is prevented from being arranged on the upper surface of the bank portion.

11. The optical semiconductor device according to claim 1,
wherein the upper surface electrode further includes a third electrode layer which is arranged on the second electrode layer and is thinner than the second electrode layer, and
wherein the third electrode layer is continuous in the second direction from an upper surface of the mesa structure portion to the first adjacent region.

12. The optical semiconductor device according to claim 1, wherein the mesa structure portion further includes the optical function layer.

13. The optical semiconductor device according to claim 12, wherein a lower surface of the optical function layer is closer to the substrate than an upper surface of the first electrode layer arranged in the first adjacent region.

14. The optical semiconductor device according to claim 1, wherein the second electrode layer contains Au.
